(19) United States
(12) Patent Application Publication
(10) Pub. No.: US 2025/0301776 A1
(43) Pub. Date: Sep. 25, 2025

(54) TRANSISTOR INTEGRATION FOR REDUCED LATERAL SPACE AND IMPROVED BREAKDOWN VOLTAGE

(71) Applicant: GlobalFoundries Singapore Pte. Ltd., Singapore (SG)

(72) Inventor: Guowei ZHANG, Singapore (SG)

(21) Appl. No.: 18/615,446

(22) Filed: Mar. 25, 2024

(51) Int. Cl. H01L 27/088; H01L 21/8234; H01L 29/06; H01L 29/08; H01L 29/66; H01L 29/78

(52) U.S. Cl. CPC H10D 84/83; H10D 30/0281; H10D 30/65; H10D 62/116; H10D 62/151; H10D 62/154; H10D 62/158; H10D 84/0151; H10D 84/038; H10D 84/151

(57) ABSTRACT

The present disclosure relates to semiconductor structures and, more particularly, to a transistor integration scheme and methods of manufacture. The structure includes: a first device on a semiconductor substrate; and a second device on the semiconductor substrate, the second device having a recessed channel region below a surface of the first device.

### BACKGROUND

The present disclosure relates to semiconductor structures and, more particularly, to a transistor integration scheme and methods of manufacture.

A laterally-diffused metal-oxide semiconductor (LDMOS) is a planar double-diffused MOSFET (metal-oxide-semiconductor field-effect transistor) used in amplifiers, including microwave power amplifiers, RF power amplifiers and audio power amplifiers. LDMOS may be integrated with other logic gates such as a low voltage gate structure on a single chip. The integration of the LDMOS with a low voltage gate structure may result in leakage issues, e.g., high leakage, or other mismatch with a baseline model especially in advanced technology nodes.

### SUMMARY

In an aspect of the disclosure, a structure comprises: a first device on a semiconductor substrate; and a second device on the semiconductor substrate, the second device comprising a recessed channel region below a surface of the first device.

In an aspect of the disclosure, a structure comprises: a first device on a first surface of a semiconductor substrate; a second device on a second surface of the semiconductor substrate, the second surface being lower than the first surface; and shallow trench isolation structures isolating the first device and the second device, the shallow trench isolation structures comprising a surface that is planar with the first surface of the semiconductor substrate.

In an aspect of the disclosure, a method comprises: forming a first device on a semiconductor substrate; and forming a second device on the semiconductor substrate, the second device being formed with a recessed channel region below a surface of the first device.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a transistor integration scheme and respective fabrication processes in accordance with aspects of the present disclosure.

FIGS. 2A-2D show fabrication processes for manufacturing the transistor integration scheme of FIG. 1.

### DETAILED DESCRIPTION

The present disclosure relates to semiconductor structures and, more particularly, to a transistor integration scheme and methods of manufacture. More specifically, the transistor integration scheme comprises one or more laterally-diffused metal-oxide semiconductor (LDMOS) devices integrated with a logic device, e.g., low voltage devices. Advantageously, the LDMOS device exhibits reduced Rdson.

In conventional integration schemes, a top oxide in a drift region design exhibits process challenges in patterning of the top oxide resulting in excessive divots in shallow trench isolation structures. These divots, in turn, cause junction leakage especially to integrated higher voltage devices which require thick oxide regions. To compensate for this phenomenon, oxide may be deposited by chemical vapor deposition (CVD) or high temperature oxide (HTO). These deposition methods, though, may result in interface traps, dangling bonds and poor quality. To address this issue, the present disclosure uses thermally grown oxide processes as described herein.

More specifically, in embodiments, the integrated device includes, for example, one or more LDMOS devices and a logic device. The channel of the LDMOS device will have a lower surface (e.g., lower surface of semiconductor material (e.g., Si)) than the logic device. The source side of the LDMOS may also have a lower surface than the drain side of the LDMOS and the logic device. The top field oxide of the LDMOS device may be formed by Local Oxidation of Silicon (LOCOS), followed by a partial etching process to form the lower surface of the channel region and source side region. The drain region of the LDMOS device may extend vertically upward compared to the channel region and the source region. This configuration will reduce a lateral space and, hence, improve Rdson vs. breakdown voltage performance.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

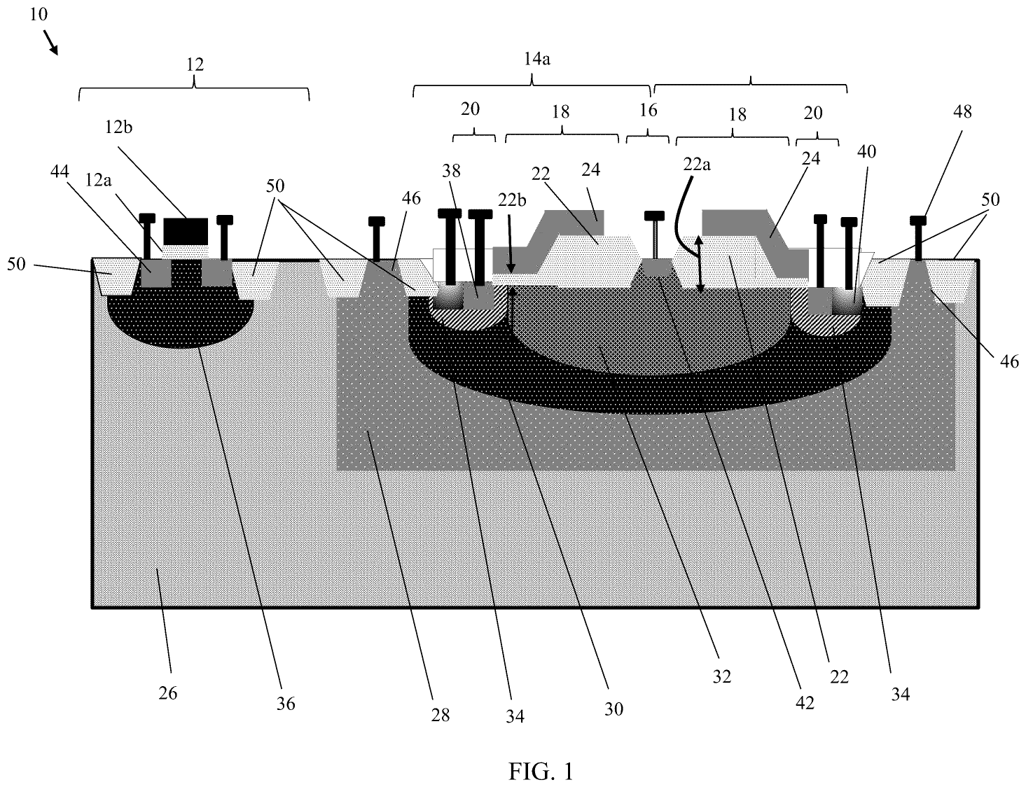

FIG. 1 shows a transistor integration scheme and respective fabrication processes in accordance with aspects of the present disclosure. More specifically, the structure 10 of FIG. 1 includes a logic device 12 integrated on a single chip with one or more high voltage devices 14a, 14b. In embodiments, the one or more high voltage devices 14a, 14b may be LDMOS devices. The one or more high voltage devices 14a, 14b may have a lower topography than the logic device 12. For example, the channel regions 18 and the source regions 20 of the one or more high voltage devices 14a, 14b may have a lower topography, e.g., top surface, than the logic device 12.

More specifically, the one or more high voltage devices 14a, 14b share a common drain region 16, e.g., drain region 16 between the one or more high voltage devices 14a, 14b. The shared drain region 16 may be a raised drain region, compared to the channel regions 18 and the source regions 20 of the one or more high voltage devices 14a, 14b. In this way, similar to a vertical MOS, there is a reduction in overall pitch and hence improved Rdson performance. Moreover, the top surface of the channel regions 18 and the source regions 20 may be lower than a top surface of the logic device 12.

Still referring to FIG. 1, the one or more high voltage devices 14a, 14b include gate structures comprising an insulator material 22 and a gate electrode 24. The gate electrode 24 may be polysilicon material, for example. The insulator material 22 may comprise a bottom surface extending below a top surface of a semiconductor material 26 and a top surface extending above the top surface of the semiconductor material 26. In embodiments, the insulator material 22 may extend between the source region 20 and the shared drain region 16 or each of the devices 14a, 14b.

In embodiments, the insulator material 22 may be a gate oxide material. In more specific embodiments, the insulator material 22 may be a thermally grown oxide and, more specifically, Local Oxidation of Silicon (LOCOS). The LOCOS may provide higher quality oxide with lesser interface traps for better reliability performance. The LOCOS 22 may have a stepped feature in which a thicker portion 22a may be closer to the shared drain region 16 over the channel region 18 and a thinner portion 22b may be closer to the source region 20 over the channel region 18. The drain region 16 may be formed in the semiconductor material 26 between the insulator material 22 of the adjacent high voltage devices 14a, 14b, at a higher level than the source regions 20.

In embodiments, the semiconductor material 26 may be composed of any suitable material including, but not limited to, Si, SiGe, SiGeC, SiC, GaAs, InAs, InP, and other III/V or II/VI compound semiconductors. In more specific embodiments, the semiconductor material 26 may be Si. The semiconductor material 26 is preferably a p-type Si semiconductor substrate with a single crystalline orientation. For example, the semiconductor material 26 may be any suitable single crystallographic orientation (e.g., a <100>, <110>, <111>, or <001> crystallographic orientation).

The semiconductor substate 26 includes a plurality of wells 28, 30, 32, 34, 36. The wells 28, 30, 32, 34 may be associated with the one or more high voltage devices 14a, 14b; whereas the well 36 may be associated with the logic device 12. The wells 32, 34, 36 may include respective diffusion regions 38, 40, 42, 44, 46. As disclosed in more detail herein, the wells 28, 30, 32, 34, 36 and diffusion regions 38, 40, 42, 44, 46 may be formed by ion implantation processes.

In embodiments, the well 28 may be a high voltage n-well, the well 30 may be a high voltage P-well and the well 32 may be an n-type high voltage double diffusion drain (HVNDDD). The n-type high voltage double diffusion drain (HVNDDD) 32 may accommodate the shared drain region 16 and the channel regions 18. The high voltage P-well 30 may isolate the high voltage n-well 28 and the n-type high voltage double diffusion drain (HVNDDD) 32, in addition to electrically connecting the wells 34. In embodiments, the wells 34 may be high voltage P-wells for the source regions 20. The well 36 may be a p-well or an n-well depending on the polarity of the logic device, e.g., NFET or PFET respectively.

The diffusion regions 38, 42, 44, 46 may be n-type diffusion regions and the diffusion regions 40 may be p-type diffusion regions. The n-type diffusion regions 38 may be source contacts in the high voltage P-wells 34 of the source region 20. The p-type diffusion regions 40 may also be provided in the high voltage P-wells 34. The n-type diffusion regions 46 may be contacts in the high voltage n-well 28. The diffusion region 46 may be a drain contact in the drain region 18 of the n-type high voltage double diffusion drain (HVNDDD) 32. The n-type diffusion regions 44 may be source and drain contacts in the well 36 of the logic device 12. The diffusion regions 38, 40 may be at a lower topography than the diffusion regions 42, 44, 46.

The wells 28, 30, 32, 34, 36 and diffusion regions 38, 40, 42, 44, 46 may be formed by introducing a dopant by, for example, ion implantation that introduces a concentration of a dopant in the semiconductor substrate 26. For example, the wells 28, 30, 32, 34, 36 and diffusion regions 38, 40, 42, 44, 46 may be formed by introducing a concentration of a different dopant of opposite conductivity type in the substrate. To accomplish these processes, respective patterned implantation masks may be used to define selected areas exposed for the implantations. The implantation mask used to select the exposed area for forming the n-type wells and diffusion regions are stripped after implantation, and before the implantation mask used to form the p-type wells and diffusion regions (or vice versa). The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The p-type wells and diffusion regions are doped with p-type dopants, e.g., Boron (B), and the n-type wells and diffusion regions are doped with n-type dopants, e.g., Arsenic (As), Phosphorus (P) and (antimony) Sb. The deeper wells may also be doped with a higher concentration of dopants than the shallower wells as is known in the art.

Metallization structures 48 (e.g., wiring structures and interconnect structures) may be formed to the diffusion regions 38, 40, 42, 44, 46. It should be understood that the metallization structures 48 may be provided at different cross-sectional views (e.g., different planes) of the structure 10. The metallization structures 48 may be formed by conventional lithography, etching and deposition processes known to those of skill in the art. For example, a resist formed over an insulator material is exposed to energy (light) and developed to form a pattern (openings). An etching process with a selective chemistry, e.g., reactive ion etching (RIE), will be used to transfer the pattern to form one or more trenches in the insulator material through the openings of the resist and to expose surfaces of the respective diffusion regions 38, 40, 42, 44, 46. Following the resist removal by a conventional oxygen ashing process or other known stripants, conductive material can be deposited by any conventional deposition processes, e.g., chemical vapor deposition (CVD) processes. Any residual material on the surface of the insulator material can be removed by conventional chemical mechanical polishing (CMP) processes.

Prior to forming the metallization structures 48, a silicide contact may be formed on the exposed surfaces of the diffusion regions 38, 40, 42, 44, 46. As should be understood by those of skill in the art, the silicide process begins with deposition of a thin transition metal layer, e.g., nickel, cobalt or titanium, over fully formed and patterned semiconductor devices (e.g., diffusion regions 38, 40, 42, 44, 46). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts in the active regions of the device.

Still referring to FIG. 1, the logic device 12 may include a gate dielectric material 12a and a gate electrode 12b on sides of the source/drain regions, e.g., diffusion regions 44. Although not critical to the understanding of the present disclosure, the logic devices 12 can be fabricated using standard CMOS or replacement gate processes using. In the standard CMOS processing, for example, the gate dielectric material 12a and gate electrode material 12b, e.g., polysilicon material, are formed, e.g., deposited, onto the semiconductor substrate 26 (at a topography or height higher than the devices 14a, 14b), followed a patterning process. An insulator material such as nitride or oxide can be deposited on the patterned materials, followed by an anisotropic etching process to form sidewalls.

Shallow trench isolation structures 50 may be formed in the semiconductor substrate 36. The shallow trench isolation structures 50 may be used to isolate the logic device 12 and the one or more high voltage devices 14a, 14b. The shallow trench isolation structures 50 may also be used to isolate the diffusion regions 46 within the high voltage n-well 28. The shallow trench isolation structures 50 have a planar surface with a top surface of the semiconductor substrate 36. This is due to the use of the LOCOS 22 and related processing steps. The shallow trench isolation structures 50 may be formed by conventional lithography, etching and deposition processes as already described herein and as understood by those of ordinary skill in the art such that no further explanation is required for a complete understanding of the present disclosure.

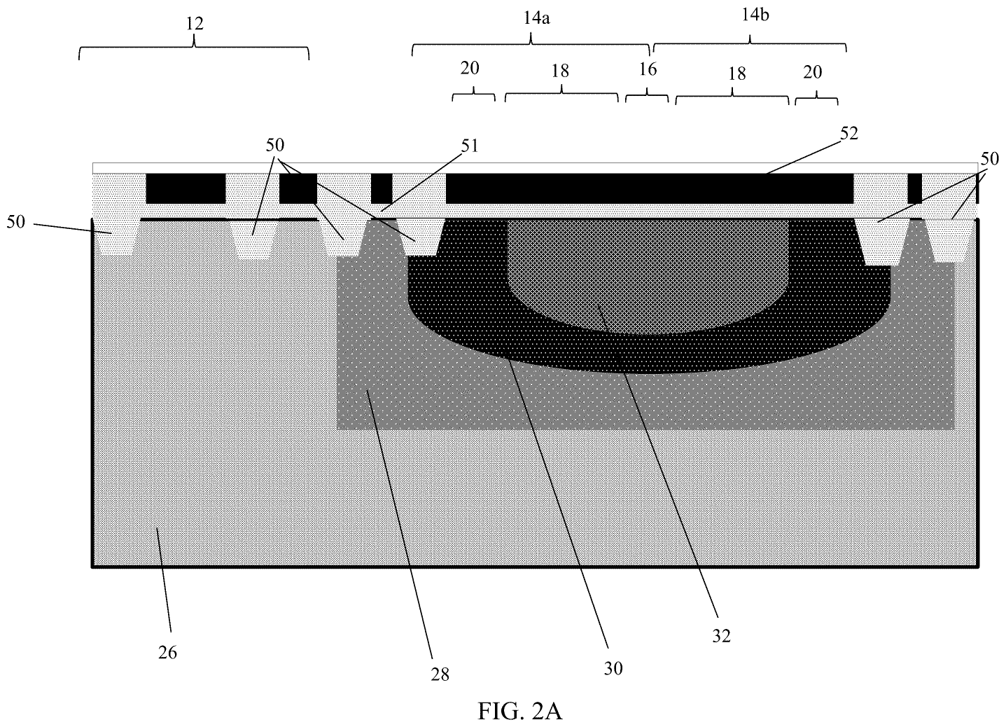

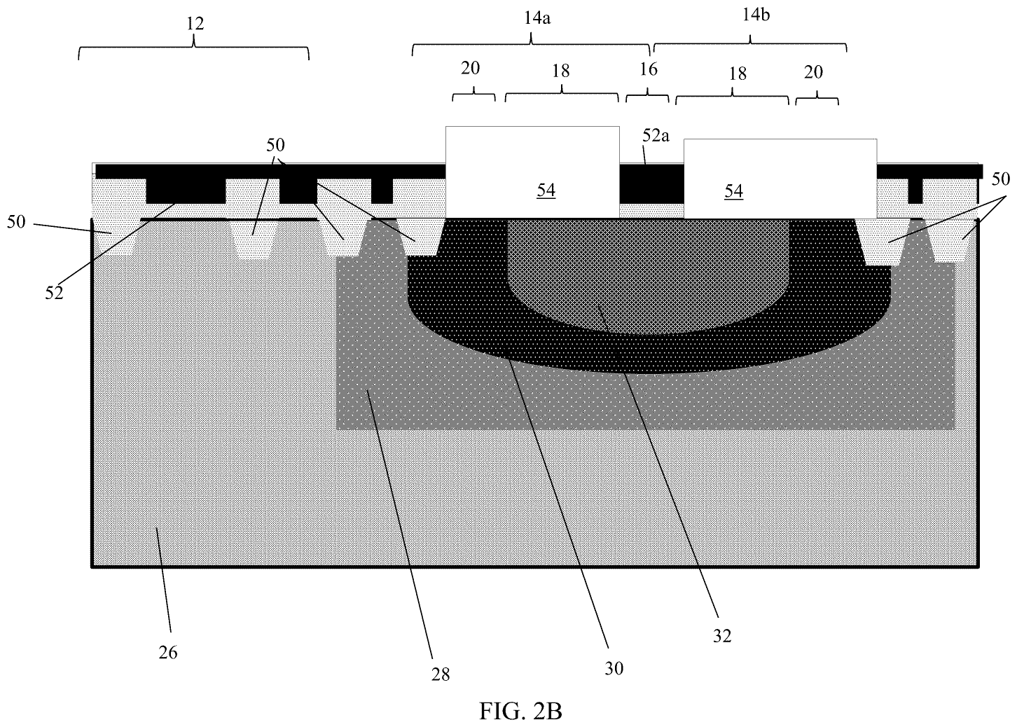

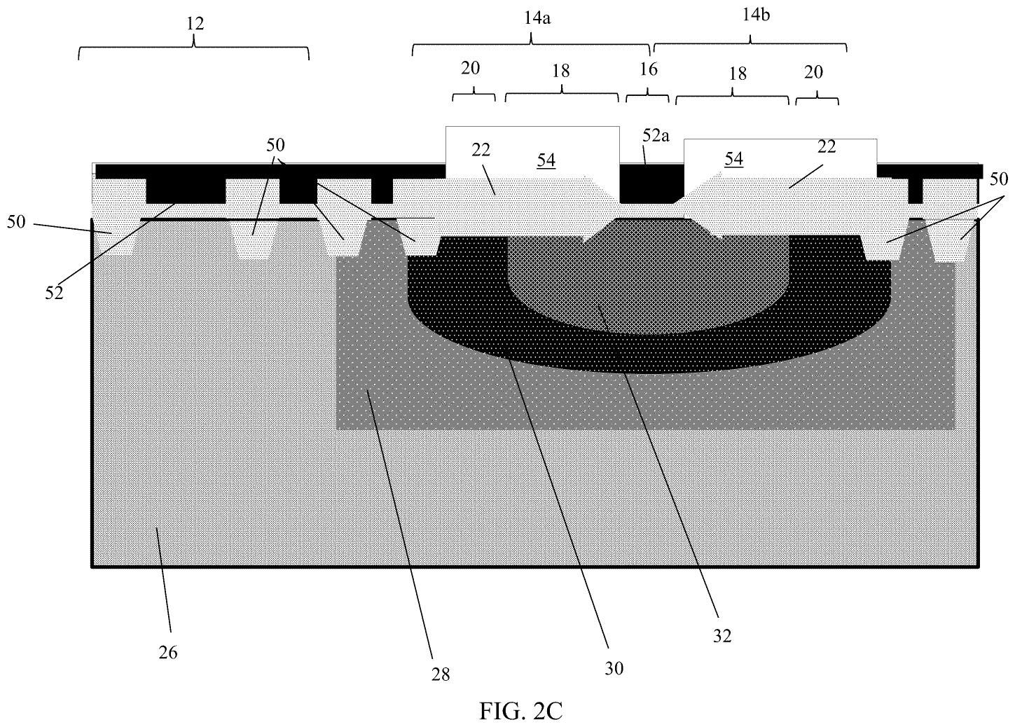

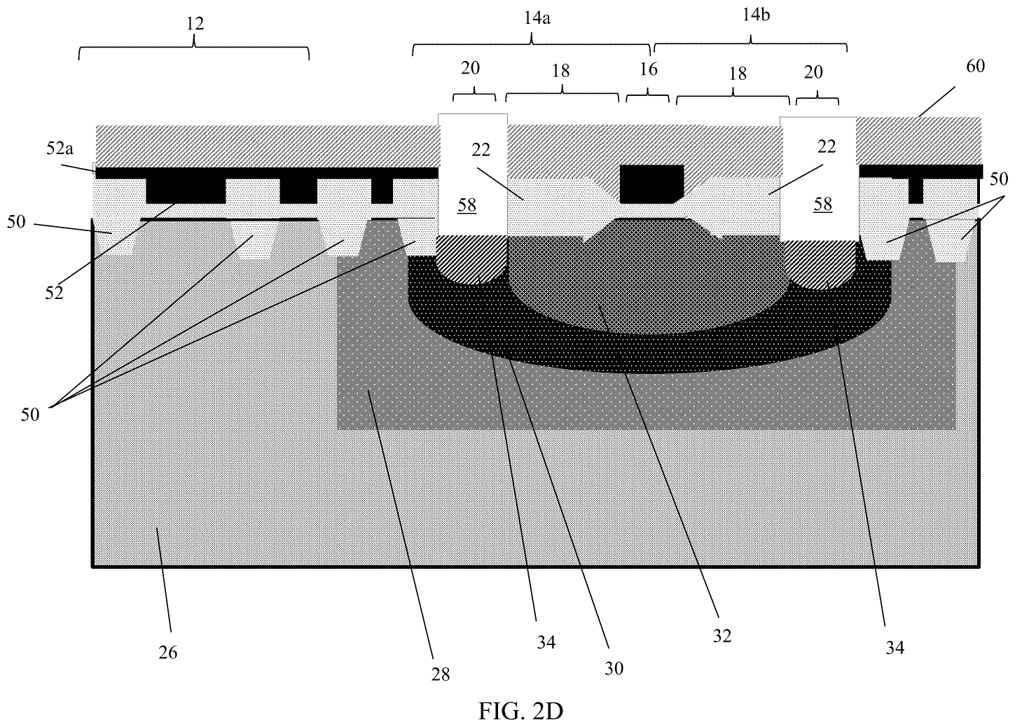

FIGS. 2A-2D show fabrication processes for manufacturing the transistor integration scheme of FIG. 1. FIG. 2A shows a starting structure with standard shallow trench isolation structure process. For example, the shallow trench isolation structures 50 may be formed by conventional lithography, etching and deposition processes. In these processes, a pad oxide layer 51 and a pad nitride layer 52 are deposited on the semiconductor substate 26. The deposition process may be, for example, a conventional CVD process.

Following the deposition process, the shallow trench isolation structures 50 can be formed by deposited a resist formed over a pad nitride layer 52, followed by a conventional lithography, e.g., exposing the resist to energy (light) and developing it to form a pattern (openings). An etching process with a selective chemistry, e.g., RIE, will be used to transfer the pattern to form one or more trenches in the semiconductor substate 26. Following the resist removal by a conventional oxygen ashing process or other known stripants, insulator material, e.g., SiO₂, can be deposited by CVD processes. Any residual material on the surface of the insulator material can be removed by conventional chemical mechanical polishing (CMP) processes. After the shallow trench isolation structures 50 are formed, the wells 28, 30, 32 can be formed by ion implantation processes as already described herein.

In FIG. 2B, an additional mask 52a may be formed over the planarized surface of the structure shown in FIG. 2A. The additional mask 52a may be SiN deposited by a conventional CVD process. The additional mask 52a and underlying material, e.g., pad oxide 51, pad nitride 52 and portions of the semiconductor substrate 26, may be patterned using conventional lithography and etching processes as described herein to form a trench 54 exposing the underlying semiconductor material 26 and, more specifically, the channel regions 18 and source regions 20. In embodiments, the etching processes will recess the semiconductor material 26 and, more specifically, the channel regions 18 and source regions 20 to below a surface of the drain region 16 and a location of the yet to be formed logic device 12. The drain region 16 remains blocked by the masking material 52, 52a and, hence, will remain vertically above the channel regions 18 and source regions 20.

In FIG. 2C, the insulator material 22 is formed in the channel regions 18 and source regions 20. More specifically, the insulator material 22 will be formed in the recessed channel regions 18 and source regions 20 below a lower surface of the drain region 16. In embodiments, the insulator material is LOCOS which forms below a surface of the semiconductor substrate 26 within the channel regions 18 and the source regions 20. During this process, the logic area 12 and the drain region 16 remain protected.

As should be understood by those of skill in the art, LOCOS is a local oxidation of semiconductor material 26, e.g., Si. In the fabrication process, for example, SiO₂ is formed in selected areas on a semiconductor substrate 26, e.g., in the drain regions 18 and the source regions 20, having, for example, the Si—SiO₂ interface at a lower point than the rest of the silicon surface. In the thermal oxidation process, a thin layer of oxide (usually silicon dioxide) is provided on the surface of the semiconductor substrate 26. The process forces an oxidizing agent to diffuse into the semiconductor substrate 26 at high temperature thus causing a reaction. Thermal oxidation may be applied to different materials, but most commonly involves the oxidation of silicon substrate 26 to produce silicon dioxide.

In FIG. 2D, a trench 58 is formed to expose the source regions 20. In embodiments, the source regions 20 may be exposed by etching through portions of the LOCOS 22. The remaining portions of the LOCOS over the channel regions 18, in addition to the drain region 16, will be protected during the etching process by a resist or mask 60 as should be understood by those of skill in the art. The high voltage P-wells 34 may be formed by an ion implantation process as described herein. Although not shown, the masks 60, 52, 52a can be removed by a conventional stripping process, e.g., etching or CMP, followed by implantation process. The additional contacts, logic device and metallization features, e.g., back end of the line processes, can continue as described in FIG. 1.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a first device on a semiconductor substrate; and
a second device on the semiconductor substrate, the second device comprising a recessed channel region below a surface of the first device,
wherein the second device comprises a gate insulator material having a first thickness thicker than a second thickness with both the first thickness and the second thickness of the gate insulator material being confined within the recessed channel region, a gate electrode on the gate insulator material also confined within the recessed channel region, and the gate insulator material with the first thickness confined within the recessed channel region extends above the recessed channel region.

2. The structure of claim 1, wherein the second device comprises a recessed source region and the gate insulator material comprises a local oxidation of semiconductor material and comprises a stepped feature comprising the first thickness and the second thickness.

3. The structure of claim 2, wherein the second device comprises a raised drain region, the raised drain region having a vertical topography higher than the recessed channel region and the recessed source region, wherein the first thickness is closer to the raised drain region and the second thickness is closer to the recessed source region.

4. The structure of claim 3, wherein the raised drain region is shared amongst the second device and a third device, the third device comprising the recessed channel region and a second recessed source region, with the third device comprising the gate insulator material and the gate electrode both extending above the recessed channel region.

5. (canceled)

6. The structure of claim 1, wherein the gate insulator material is a local oxidation of the semiconductor substrate.

7. The structure of claim 6, wherein the local oxidation of the semiconductor substrate comprises a bottom surface in the recessed channel region, and the bottom surface is below a surface of the semiconductor substrate and a top surface is above the surface of the semiconductor substrate.

8. The structure of claim 1, wherein the second device comprises a laterally-diffused metal-oxide semiconductor device and the first device comprises a logic device.

9. The structure of claim 1, further comprising shallow trench isolation structures isolating the first device and the second device, the shallow trench isolation structures having a planar surface with a top surface of the semiconductor substrate.

10. A structure comprising:
a first device on a first surface of a semiconductor substrate;
a second device on a second surface of the semiconductor substrate, the second surface being lower than the first surface and being defined as a recessed channel region, the second device comprising an insulator material with a stepped feature comprising various thicknesses and a gate electrode on the stepped feature of the insulator material within the recessed channel region, wherein the various thicknesses include a first thickness thicker than a second thickness both of which are confined within the recessed channel region, the gate insulator with the first thickness extends above the recessed channel region; and
shallow trench isolation structures isolating the first device and the second device, the shallow trench isolation structures comprising a surface that is planar with the first surface of the semiconductor substrate.

11. The structure of claim 10, wherein the recessed channel region is below the first surface and the first device.

12. The structure of claim 11, wherein the second device comprises a recessed source region and a raised drain region.

13. The structure of claim 12, wherein the raised drain region comprises a vertical topography higher than the recessed channel region and the recessed source region.

14. The structure of claim 13, further comprising a third device on the second surface of the semiconductor substrate, the third device comprising the raised drain region shared with the second device.

15. The structure of claim 14, wherein the third device comprises a second recessed channel region and a second recessed source region.

16. The structure of claim 11, further comprising an oxide material over the recessed channel region of the second device, extending from a raised drain region to a recessed source region of the second device.

17. The structure of claim 16, wherein the oxide material is a local oxidation of the semiconductor substrate.

18. The structure of claim 17, wherein the local oxidation of the semiconductor substrate comprises a bottom surface in the recessed channel region of the second device that is below the first surface of the semiconductor substrate, and a top surface above the second surface of the semiconductor substrate.

19. The structure of claim 10, wherein the second device comprises a laterally-diffused metal-oxide semiconductor device and the first device comprises a logic device.

20. A method comprising:
forming a first device on a semiconductor substrate; and
forming a second device on the semiconductor substrate, the second device being formed with a recessed channel region below a surface of the first device,
wherein the second device comprises a gate insulator material having a first thickness thicker than a second thickness with both the first thickness and the second thickness of the gate insulator material being confined within the recessed channel region, a gate electrode on the gate insulator material also confined within the recessed channel region, and the gate insulator material with the first thickness confined within the recessed channel region extends above the recessed channel region.

21. The structure of claim 10, wherein the stepped feature comprises a first thickness adjacent to a source region of the second device and a second thickness adjacent to a raised drain region of the second device.

22. The structure of claim 10, wherein a first thickness is different from a second thickness.
